(19) United States
(12) Patent Application Publication
(10) Pub. No.: US 2008/0238246 A1
(43) Pub. Date: Oct. 2, 2008

(54) Electromechanical actuator

(75) Inventor: David P. Smith, Reddick, IL (US)

Correspondence Address: CATERPILLAR/FINNEGAN, HENDERSON, L.L.P., 901 New York Avenue, NW, WASHINGTON, DC, 20001-4413, US

(73) Assignee: CATERPILLAR INC.

(21) Appl. No.: 11/729,921

(22) Filed: Mar. 30, 2007

(51) Int. Cl. H01L 41/02

(52) U.S. Cl. 310/314

(57) ABSTRACT

An actuator includes a frame and a shaft rotabably supported by the frame. The actuator also includes at least one wire made from a shape memory alloy having a first end thereof fixed with respect to the frame. A second end of the at least one wire is movable with respect to the frame and configured to rotate the shaft in a first direction with respect to the frame.

### TECHNICAL FIELD

The present disclosure relates to an actuator and, more particularly, to an electromechanical actuator.

### BACKGROUND

Actuators typically convert one type of energy, e.g., electrical, chemical, or hydraulic energy, into another type of energy, e.g., mechanical energy. The mechanical energy is often used to perform some type of work, e.g., rotate a shaft, displace a linkage, or effect movement of one or more devices. Electrical joysticks that convert operator displacement of an interface device, e.g., a lever, into electrical signals often have one or more actuators operatively associated therewith to provide tactile feedback to the operator. For example, the electrical signals are often input into a controller that controls one or more devices, e.g., valves, to effect a desired operation. Because the joystick is mechanically decoupled from the devices, the operator may not experience resistance when displacing it. As such, the one or more actuators operatively associated with the joystick may be controlled by the controller to actuate and provide resistance to the operator via the interface device as a function of one or more parameters, e.g., the displacement of the joystick or the load on the devices.

U.S. Pat. No. 4,439,987 (“the '987 patent”) issued to Rideout, Jr. discloses a prime mover operated primarily by ambient atmospheric temperatures on a day and night cycle. The prime mover includes a coiled tubular metal member supported by a tower and subject to expansion and contraction during each cycle. The metal member includes an inner and an outer coil with end portions operatively connected to one end of a lever. The lever extends substantially parallel to the longitudinal axis of the inner and outer coils and pivots about a fulcrum located relatively close to the end of the lever operatively connected to the end portions of the inner and outer coils. At an opposite end of the lever, an arcuate rack is enmeshed with a pinion. As the metal member expands and contracts the arcuate rack rotates the pinion.

Although, the prime mover of the '987 patent may convert heat into rotary movement, the extension and contraction of the metal member may be unsatisfactorily small, e.g., approximately 0.01% of length, and/or require a metal member of substantial length, e.g., hundreds of feet. Additionally, the frequency at which the prime mover of the '987 patent actuates may be unsatisfactorily long and/or require a significant amount of additional heat energy to shorten. Furthermore, the metal member of the prime mover of the '987 patent extends when heated and contracts when cooled, establishing movement from a neutral position, e.g. the contracted position, in a single direction, e.g., the extracted position.

The present disclosure is directed to overcoming one or more of the shortcomings set forth above.

### SUMMARY OF THE INVENTION

In one aspect, the present disclosure is directed to an actuator including a frame and a shaft rotabably supported by the frame. The actuator also includes at least one wire made from a shape memory alloy having a first end thereof fixed with respect to the frame. A second end of the at least one wire is movable with respect to the frame and configured to rotate the shaft in a first direction with respect to the frame.

In another aspect, the present disclosure is directed to an actuator. The actuator includes a first wire formed from a shape memory alloy and a second wire formed from a shape memory alloy. The actuator also includes a frame supporting the first and second wires and includes a shaft operatively connected to respective first ends of the first and second wires. The shaft is configured to rotate in first direction as a function of a dimensional change of the first wire and rotate in a second direction, opposite the first direction, as a function of a dimensional change of the second wire.

### BRIEF DESCRIPTION OF THE DRAWINGS

FIG. 1 is a diagrammatic illustration of an exemplary actuator in accordance with the present disclosure;

FIG. 2 is a diagrammatic illustration of view A-A of the actuator of FIG. 1;

FIG. 3 is a diagrammatic illustration of view B-B of the actuator of FIG. 1;

FIG. 4 is a diagrammatic illustration of view C-C of the actuator of FIG. 1;

FIG. 5 is a diagrammatic illustration of an exemplary actuator in accordance with the present disclosure; and

FIG. 6 is a diagrammatic illustration of an operator interface device with which the actuator of either FIG. 1 or FIG. 5 may be associated.

### DETAILED DESCRIPTION

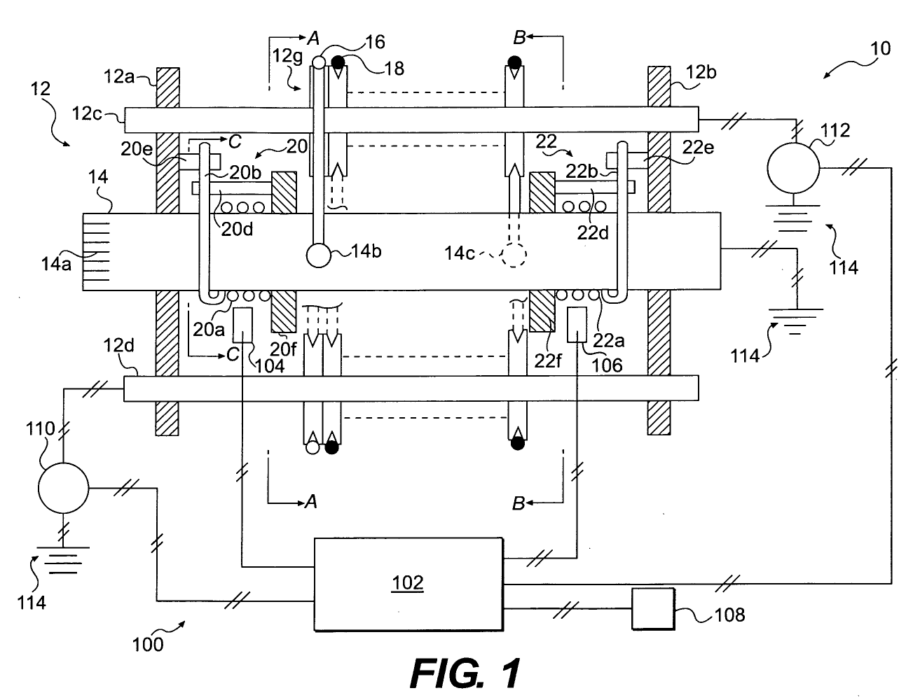

FIG. 1 illustrates an exemplary actuator 10. Specifically, actuator 10 may include a frame 12 configured to rotatably support a shaft 14 and configured to support first and second wires 16, 18. Actuator 10 may also include first and second torsional springs 20, 22 operatively connected between frame 12 and shaft 14. Actuator 10 may also include a control system 100 including a controller 102, first and second sensors 104, 106, inputs 108, and first and second sources 110, 112 of electrical potential. Actuator 10 may be configured to produce a mechanical output, e.g., rotary movement of shaft 14, by selectively affecting a dimensional change in the first and/or second wires 16, 18 as a function of heat supplied thereto. Actuator 10 is described with reference to an electrical potential as the manner in which heat is supplied to first and second wires 16, 18, however, it is contemplated that actuator 10 may include any source of heat. It is also contemplated that the overall dimensions of actuators 10, 10′, in an exemplary embodiment, may be approximately one cubic centimeter in volume and may have length, width, and height dimensions of approximately 10 mm per side.

Frame 12 may be configured to rotatably support shaft 14 via first and second end-plates 12a-b, and support first and second wires 16, 18 via a plurality of columns 12c-f. End-plates 12a-b may rotatably support shaft 14 via one or more bearings (not shown) or bearing surfaces (not referenced) disposed therebetween. Columns 12c-f may be fixed at one end thereof to first end-plate 12a and fixed at a second end thereof to second end-plate 12b and may support first and second wires 16, 18 via a plurality of pulleys 12g. Pulleys 12g may be rotatably disposed on columns 12c-f and may be configured to reduce a frictional resistance during contraction and extension between first and second wires 16, 18 and frame 12. Pulleys 12g may include any conventional pulley device having an arcuate outer surface and supported on a respective one of columns 12c-f via a bearing (not shown) or a bearing surface (not referenced). It is contemplated that first and second end-plates 12a-b may include any shape, e.g., circular, square, triangular, or x-shape, and that frame 12 may include any quantity of columns. It is also contemplated that pulleys 12g may or may not include a groove (not referenced) on the arcuate outer surface thereof in which a respective one of first and second wires 16, 18 may be supported.

Shaft 14 may be configured as an output member of actuator 10. Specifically, shaft 14 may include splines 14a for connection to one or more output devices, e.g., another shaft or gear train, for mutual rotation with shaft 14. Shaft 14 may also include first and second levers 14b-c operatively connected to shaft 14. For example, first and second levers 14b-c may be fixed at a respective first end thereof to shaft 14 and may extend radially outward therefrom. A respective second end of first and second levers 14b-c may be operatively connected to first and second wires 16, 18. As such, selective displacement of either first or second displacement member 16, 18 may affect shaft 14 to rotate by applying a moment thereto via either first or second lever 14b-c. It is contemplated that shaft 14 may include splines at either or both ends thereof. It is also contemplated that first and second levers 14b-c may include any shape, e.g., a circular plate, a partial flange, and/or a pin having any cross-sectional shape. It is also contemplated that first and second levers 14b-c may also be configured as outputs of actuator 10 and may be connected to one or more output devices to provide reciprocating movement thereto. It is further contemplated that multiple actuators, e.g., actuator 10, may include respective shafts thereof, e.g., shaft 14, connected to a common output device, e.g., a shaft, via respective one-way clutches to provide a substantially continuous rotary output thereto.

Shaft 14 may be configured to rotate a given amount, e.g., 20 degrees, in a first direction from a neutral position as a function of the contraction of first wire 16 and rotate a given amount, e.g., 20 degrees, in a second direction opposite the first direction from the neutral position as a function of the contraction of second wire 18. It is further contemplated that shaft 14 may be rotated at a frequency of approximately 10 Hertz or more and that a force of approximately 20 Newtons may be applied to shaft 14 which may correspond to a shaft torque of approximately 0.1 Newton-meter, e.g., 20 Newtons times 5 mm moment arm (half of an actuator side dimension).

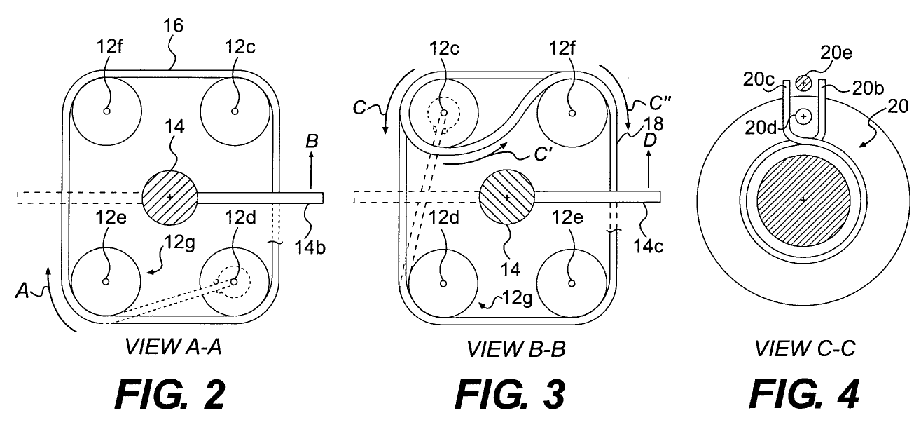

First and second wires 16, 18 may be formed from any shape memory material, such as, for example, flexinol or nitinol, and may be supported on frame 12 via columns 12c-f. For example, shape memory materials may be formed from nickel and titanium and dynamically change their internal structure as a function of temperature. First and second wires 16, 18 may include a transition temperature below which the wire contracts and above which the wire extends to its original length. First and second wires 16, 18 may each include a plurality of bends forming a spiral shape about frame 12 and may both extend in the same direction. That is, first and second wires 16, 18 may both extend in a clockwise direction or may both extend in a counterclockwise direction about frame 12 as viewed from a common side of frame 12. For clarification purposes, all references to clockwise and counterclockwise directions made herein are made as if viewed from view A-A in FIG. 1. A first respective end of each of first and second wires 16, 18 may be electrically connected and fixed to one of columns 12c-f, e.g., column 12d and column 12c, respectively, and a second respective end of each of first and second wires 16, 18 may be electrically connected and fixed to a respective one of first and second levers 14b-c. Upon contraction of first wire 16, shaft 14 may be rotated in a first direction, e.g., counterclockwise, and upon contraction of second wire 18, shaft 14 may be rotated in a second direction opposite the first direction, e.g., clockwise. The manner in which first and second wires 16, 18 may be configured to both extend in the same direction about frame 12 and rotate shaft 14 in opposite direction will be described below with reference to FIGS. 2 and 3. It is contemplated that first and second wires 16, 18 may have any cross-sectional shape, e.g., circular, square, or triangular. It is also contemplated that spiral loops of first and second wires 16, 18 may alternate along a longitudinal dimension of frame 12 and/or one of first or second wires 16, 18 may be supported on columns 12c-f via pulleys having a dimension smaller than pulleys supporting the other one of first or second wires 16, 18. It is further contemplated that in an exemplary embodiment first and second wires 16, 18 may be approximately 200 mm in length and may contract approximately 4% thereof, e.g., 8 mm, when heated above a given temperature, e.g., a transition temperature.

First and second torsional springs 20, 22 may be disposed between frame 12 and shaft 14 and may be configured to be stressed as a function of the rotation of shaft 14. First and second torsional springs 20, 22 may each include any conventional torsional spring having one or more bends forming a respective coil 20a, 22a and a respective pair of tangs 20b-c, 22b-c. Each pair of tangs 20b-c, 22b-c may be disposed on opposite sides of a respective movable pin 20d, 22d and a respective fixed pin 20e, 22e. Movable pins 20d, 22d may be fixed with respect to shaft 14 for rotation therewith and may extend substantially parallel thereto. Fixed pins 20e, 22e may be fixed with respect to frame 12 and may extend substantially parallel to shaft 14. It is contemplated that movable pins 20d, 22d may be connected to shaft 14 via a respective flange 20f, 22f and that fixed pins 20e, 22e may be connected to end-plates 12a, 12b. It is also contemplated that one of first and second torsional springs 20, 22 may be selectively omitted. It is further contemplated that first and second levers 14b-c may be connected to and/or embody flanges 20f, 22f. First and second torsional springs 20, 22 are further described below with reference to FIG. 4.

Control system 100 may be configured to selectively supply an electrical potential to first and second wires 16, 18. Controller 102 may include one or more microprocessors, a memory, a data storage device, a communications hub, and/or other components known in the art. Controller 102 may be configured to receive input signals from first and second sensors 104, 106, and inputs 108, perform one or more algorithms to determine appropriate output signals, and may deliver the output signals to affect control of actuator 10. First and second sensors 104, 106 may each include a force sensing resistor sensor or other conventional sensor configured to produce a signal indicative of the stress of first and second torsional springs 20, 22, respectively. Inputs 108 may include one or more signals indicative of a magnitude and/or operation of one or more devices, for example, indicative of a degree of displacement of an operator interface device. Sources 110, 112 of electrical potential may include any conventional voltage or current source and may be alternating or direct current. For example, source 110 may be electrically connected to column 12d and source 112 may be electrically connected to column 12c. Shaft 14 may be connected to ground 114 to complete respective circuits from sources 110, 112 of electric potential, columns 12d, 12c, first and second wires 16, 18, first and second levers 14b, 14c, shaft 14, and ground 114. It is contemplated that columns 12d, 12c, first and second levers 14b, 14c, shaft 14 may each be formed from a material configured to conduct electricity and/or heat such as, for example, steel.

FIG. 2 illustrates first wire 16 with respect to columns 12c-f. Specifically, first wire 16 may include a plurality of bends and may be wrapped about columns 12c-f in the direction indicated by arrow A, e.g. clockwise. For example, the first end of first wire 16 may be fixedly connected to column 12d via any conventional connection, e.g., a wire clamp or welded, and may extend toward column 12e. First wire 16 may be wrapped about column 12e and supported thereon via one of pulleys 12g. First wire 16 may extend toward columns 12f, 12c, 12d, respectively, forming a spiral loop. First wire 16 may similarly extend about columns 12c-f to form additional spiral loops establishing a spiral shape having any number of spiral loops. The second end of first wire 16 may be fixedly connected to first lever 14b via any conventional connection, e.g., wire clamp or welded. As such, upon contraction of first wire 16, the second end thereof may cause first lever 14b to move in the direction indicated by arrow B which may cause shaft 14 to rotate about the longitudinal axis thereof. For example, a contraction of first wire 16 may affect a rotation of shaft 14 in a counterclockwise direction. It is contemplated that first wire 16 may extend about columns 12c-f in a counterclockwise direction and contraction thereof may affect a rotation of shaft 14 in a clockwise direction. It is also contemplated that the first end of first wire 16 may be fixedly connected to any of columns 12c-f and that first lever 14b may extend radially outward from shaft 14 at any angle and may be positioned with respect to any of columns 12c-f.

FIG. 3 illustrates second wire 18 with respect to supports 12c-f. Specifically, second wire 18 may include a plurality of bends and may be wrapped about columns 12c-f in a direction indicated by arrow C. Direction C may be the same direction with respect to columns 12c-f and frame 12 as direction A (referring to FIG. 2), e.g., clockwise, as viewed from view A-A (referring to FIG. 1). For example, the first end of second wire 18 may be fixedly connected to column 12c via any conventional connection, e.g., a wire clamp or welded, and may extend toward column 12d. Second wire 18 may be wrapped about column 12d and supported thereon via one of pulleys 12g. Second wire 18 may extend toward columns 12e, 12f, 12c, respectively, forming a spiral loop. Second wire 18 may similarly extend about columns 12c-f to form additional spiral loops establishing a spiral shape having any number of spiral loops. The last loop of second wire 18 may extend from column 12c toward column 12f in a direction indicated by arrow C′ and may pass between columns 12c, 12f and around column 12f in a direction indicated by arrow C″ forming a partial “figure 8” shape. The second end of second wire 18 may be fixedly connected to second lever 14c via any conventional connection, e.g., wire clamp or welded. As such, upon contraction of second wire 18, the second end thereof may cause second lever 14c to move in the direction of arrow D, opposite direction B, which may cause shaft 14 to rotate about the longitudinal axis thereof. For example, a contraction of second wire 18 may affect a rotation of shaft 14 in a clockwise direction. It is contemplated that second wire 18 may extend about columns 12c-f in a counterclockwise direction and contraction thereof may affect a rotation of shaft 14 in a counterclockwise direction. It is also contemplated that the first end of second wire 18 may be fixedly connected to any of columns 12c-f and that second lever 14c may extend radially outward from shaft 14 at any angle and may be positioned between any of columns 12c-f. It is further contemplated that the position of the partial “figure 8” shape may extend between any two columns depending upon the position of second lever 14c.

FIG. 4 illustrates first torsional spring 20 with respect to frame 12 and shaft 14. First pair of tangs 20b-c may be positioned on opposite sides of movable and fixed pins 20d-e. First torsional spring 20 my be stressed as a function of shaft 14 rotating in either a clockwise or counterclockwise direction and corresponding movement of movable pin 20d therewith displacing one of the first pair of tangs 20b-c with respect to the other of the first pair of tangs 20b-c substantially held in place by fixed pin 20e. The operation of torsional springs is well known in the art and, as such, first torsional spring 20 is not further described. It is contemplated that second torsional spring 22 is substantially similar to torsional spring 20 and is accordingly not further described.

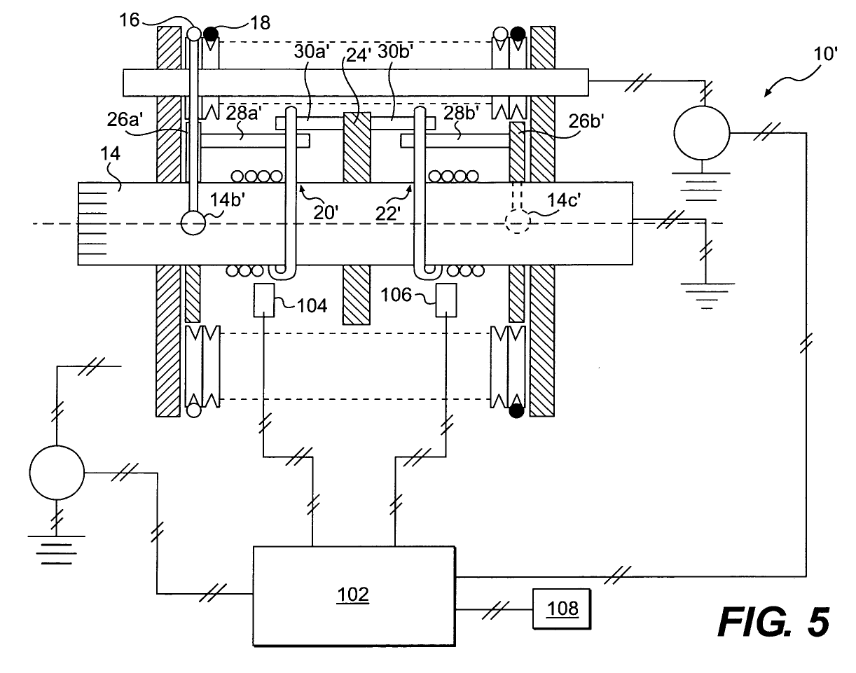

FIG. 5 illustrates another exemplary actuator 10′. Actuator 10′ is similar to actuator 10 and only the differences will be described. Shaft 14 may include a fixed flange 24′ fixedly connected thereto and configured to rotate therewith and may also include first and second flanges 26a′-b′ rotatably supported on shaft 14. First and second levers 14b′-c′ may be operatively connected to shaft first and second flanges 26a′-b′. For example, first and second levers 14b′-c′ may be fixed at a respective first end thereof to a respective one of first and second flanges 26a′-b′ and may extend radially outward therefrom. A respective second end of first and second levers 14b′-c′ may be operatively connected to first and second wires 16, 18. As such, selective displacement of either first or second wires 16, 18 may affect first and second flanges 26a′-b′ to rotate by applying a moment thereto via either first or second lever 14b′-c′.

First and second flanges 26a′-b′ may also include respective first pins 28a′-b′ fixed thereto and extending therefrom substantially parallel to shaft 14. First pins 28a′-b′ may extend between a respective pair of tangs of first and second torsional springs 20′, 22′. Fixed flange 24′ may include second pins 30a′-b′ fixed thereto and extending therefrom substantially parallel to shaft 14. Second pins 30a′-b′ may extend between a respective pair of tangs of first and second torsional springs 20′, 22′. As such, selective rotation of one of first and second flanges 26a′-b′ in a first direction, e.g., clockwise, may rotate respective first pins 28′a-b′, which may stress first and second torsional springs 20′, 22′, which may rotate second pins 30a′-b′, fixed flange 24′, and shaft 14 in the first direction, e.g., clockwise. It is contemplated that first pins 28a′-b′ may stress first and second torsional springs 20′, 22′ by affecting movement of one of the associated pair of tangs. The other one of the associated pair of tangs may affect movement of second pins 30a′-b′ as a function of the movement of the associated one of first pins 28a′-b′ and the stress of the respective one of first and second torsional springs 20′, 22′. The operation of first and second torsional springs 20′, 22′ is well known in the art and is not further described. It is contemplated that selective rotation of first and second flanges 26a′-b′ in a second direction, opposite the first direction, e.g., counterclockwise, may similarly affect rotation of shaft 14 in the second direction, e.g., counterclockwise.

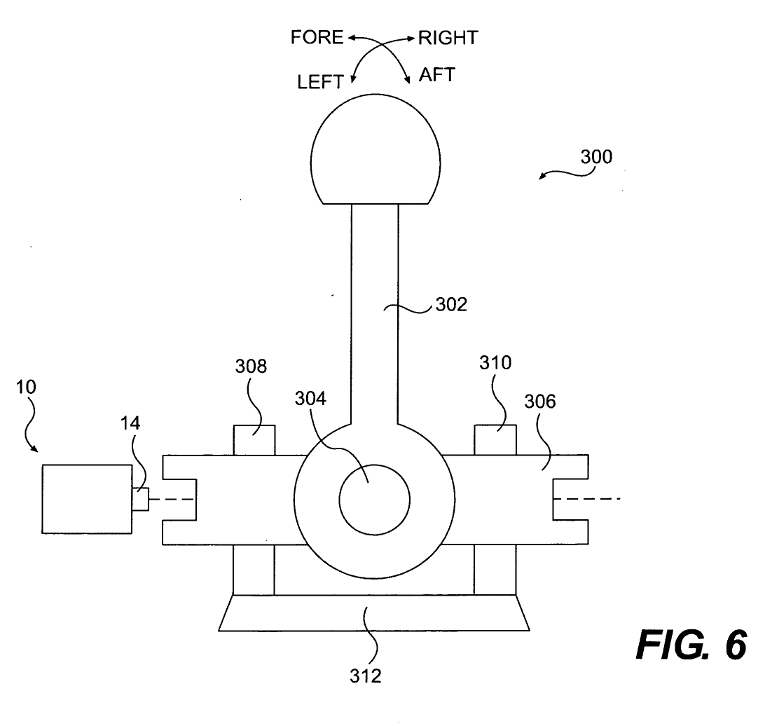

FIG. 6 illustrates an exemplary operator interface device 300. Operator interface device 300 may include a lever 302 coupled to a mounting base 312 via a universal coupling formed by first and second shafts 304, 306. Base 312 may include first and second lugs 308, 310 defining bores configured to rotatably support second shaft 306. Lever 302 may include a bore therein configured to rotatably support shaft 304. Operator interface device 300 may be movable in multiple axis generically referenced as the fore, aft, left, and right directions in FIG. 6 and may be configured to produce one or more signals that may be communicated to controller 102 as one of inputs 108 (referring to FIGS. 1 and 5). One of actuators 10 or 10′ (not shown) may be operatively connected to shaft 306 and/or one of actuators 10 or 10′ may be operatively connected to shaft 304 (not shown) via, for example, shaft 14 fixedly connected to shaft 306 for mutual rotation therewith. As such, rotation of shaft 14 may affect rotation of one of shafts 304, 306. It is contemplated that operator interface device may be movable in a single axis and/or in multiple axis and may include various other additional components known in the art. It is also contemplated that operator interface device 300 may include a joystick, a push button, a dial, and/or any other type of operator interface device known in the art. The operation of operating interface device 300 is well known in the art and is not further described.

### INDUSTRIAL APPLICABILITY

The disclosed actuator may be applicable to produce rotary motion. The disclosed actuator may apply motion and/or force to an operator interface device 300, e.g., a joystick, to provide tactile and/or haptic feedback to an operator. The operation of actuators 10 and 10′ are explained below.

Referring to FIG. 1, controller 102 may selectively supply electrical energy, e.g., voltage and/or current, to first wire 16. Heat may be generated within first wire 16 due to the conductional resistance and first wire 16 may contract as a function of the supplied electrical energy and the generated heat. Contraction of first wire 16 may, via first shaft 14b, cause shaft 14 to rotate in a first direction. Rotation of shaft 14 may stress first torsional spring 20, first sensor 104 may produce a signal indicative of the stress of first torsional spring 20, and controller 102 may receive the signal produced by first sensor 104. Controller 102 may selectively supply electrical energy, e.g., voltage and/or current, to second wire 18 to similarly cause shaft 14 to rotate in a second direction opposite the first direction. Controller 102 may also receive a signal produced by second sensor 106 indicative of the stress of second torsional spring 22.

Referring to FIG. 5, controller 102 may selectively supply electrical energy, e.g., voltage and/or current, to first and second wires 16, 18. Contraction of first wire 16 may, via first lever 14b′, cause first flange 26′ to rotate in a first direction. Rotation of flange 26′ may stress first torsional spring 20′ which may, in turn, cause fixed flange 24′ and shaft 14 to rotate in the first direction. First sensor 104 may produce a signal indicative of the stress of first torsional spring 20′ and controller 102 may receive the signal produce by first sensor 104. Contraction of second wire 18 may similarly cause shaft 14 to rotate in a second direction opposite the first direction. Controller 102 may also receive a signal produced by sensor 106 indicative of the stress of second torsional spring 22′.

Controller 102 may selectively supply electrical energy to first and second wires 16, 18 as a function of inputs 108. For example, controller 102 may receive inputs 108 indicative of the displacement of operator interface device 300 (see FIG. 6). Controller 102 may perform one or more algorithms as a function of inputs 108 and may selectively supply electrical energy to first and second wires 16, 18. As such, shaft 14 may rotate in either the first or second direction and actuators 10, 10′ may produce a rotary output as a function of the selectively supplied electrical energy.

Referring to FIG. 1 and actuator 10, controller 102 may also determine an amount of rotation of shaft 14 as a function of the signals received from first and second sensors 104, 106. For example, controller 102 may receive a signal from first sensor 104 indicative of the stress of first torsional spring 20. Controller 102 may compare the received signal with one or more predetermined values and/or ranges. For example, controller 102 may compare the signal received from first sensor 104 with a first predetermined value indicative of a given number of degrees of rotation of shaft 14 and may determine that shaft 14 has rotated the given number of degrees if the signal received from first sensor 104 is greater than the first predetermined value. For another example, controller 102 may compare the signal received from first sensor 104 with a second predetermined value indicative of a force applied to shaft 14 and may determine that shaft 14 has the given force applied to it by the contraction of first wire 16 if the signal received from first sensor 104 is greater than the second predetermined value. It is contemplated that controller 102 may similarly determine rotation of and/or force applied to shaft 14 as a function of a signal received from second sensor 106 and the stress of second torsional spring 22. It is also contemplated that controller 102 may include one or more look-up tables, multi-dimensional maps, and/or any other functional relations to determine an amount of rotation of and/or force applied to shaft 14 as a function of the stress of first and/or second torsional springs 20, 22.

Referring to FIG. 5 and actuator 10′, controller 102 may determine a load acting on shaft 14 as a function of the signals received from first and second sensors 104, 106. For example, controller 102 may receive a signal from first sensor 104 indicative of the stress of first torsional spring 20′ and may receive a signal from second sensor 106 indicative of the stress of second torsional spring 22′. Controller 102 may compare the signals received from first and second sensors 104, 106 with one or more predetermined values and/or ranges. For example, controller 102 may compare the signal received from first sensor 104 with the signal received from second sensor 106 and may determine the force applied to shaft 14 from the contraction of first wire 16 and the force applied to shaft 14 from a resistive load as a function of the difference between the two signals. It is contemplated that controller 102 may include one or more look-up tables, multi-dimensional maps, and/or any other functional relations to determine an amount of rotation of, force applied to, and/or load resistance on shaft 14 as a function of the stress of first and/or second torsional springs 20′, 22′. It is contemplated that controller 102 may compare a signal received from first or second sensor 104, 106 with a first and/or second predetermined values to determine an amount of rotation and/or force applied to shaft 14 as explained above with reference to FIG. 1 and actuator 10. It is also contemplated that if controller 102 is configured to determine an amount of force applied to shaft 14 as a function of the signals received from first and/or second sensors 104, 106, controller 102 may be configured to receive an additional rotational feedback signal, for example, from an operator interface device via inputs 108 and/or via an additional sensor adjacent shaft 14 or first and/or second torsional springs 20′, 22′.

Referring to FIG. 6, shaft 14 may be operatively connected to shaft 306 and may provide rotary motion thereto. The rotary motion supplied to shaft 306 may be in a direction opposite the direction that an operator displaced operator interface device 300 and thus may provide a tactile feedback to the operator. It is contemplated that a tactile feedback may be provided for numerous reasons, such as, for example, the operator has displaced operator interface device 300 past a predetermined displacement and increased resistance to continued displacement may be desired to provide an indication to the operator that the predetermined displacement has been reached.

Because contraction of first and second wires 16, 18 affect rotation of shaft 14 in opposite directions, actuators 10, 10′ may be dual direction actuators. Additionally, because first and second wires 16, 18 may formed from shape memory alloys and may have spiral shapes, actuators 10, 10′ may provide a relatively small actuator with significant force and/or rotary movement output.

It will be apparent to those skilled in the art that various modifications and variations can be made to the disclosed actuator. Other embodiments will be apparent to those skilled in the art from consideration of the specification and practice of the disclosed method and apparatus. It is intended that the specification and examples be considered as exemplary only, with a true scope being indicated by the following claims and their equivalents.

What is claimed is:

1. An actuator comprising:
a frame;
a shaft rotabably supported by the frame; and
at least one wire made from a shape memory alloy including:
a first end thereof fixed with respect to the frame, and
a second end thereof movable with respect to the frame and configured to rotate the shaft in a first direction with respect to the frame.

2. The actuator of claim 1, further including at least one lever having a first end thereof fixed with respect to the shaft and a second end thereof operatively connected to the second end of the at least one wire.

3. The actuator of claim 1, wherein the at least one wire is a first wire and the actuator further includes:
a second wire made from a shape memory alloy including:
a first end thereof fixed with respect to the frame, and
a second end thereof movable with respect to the frame and configured to rotate the shaft in a second direction with respect to the frame.

4. The actuator of claim 3, wherein the first and second directions are different.

5. The actuator of claim 1, wherein:
the frame includes a first end plate, a second end plate, and a plurality of links interconnecting the first and second end plates; and
the at least one wire includes a plurality of bends and is supported via the plurality of links.

6. The actuator of claim 1, wherein:
the frame includes a first end plate, a second end plate, and a plurality of links interconnecting the first and second end plates;
the at least one wire includes a first wire wrapped around and supported via the plurality of links in a first direction and a second wire wrapped around and supported via the plurality of links in a second direction.

7. The actuator of claim 6, wherein the first and second directions each extend in the same direction.

8. The actuator of claim 1, wherein the shape memory alloy is nitinol.

9. The actuator of claim 1, further including:
at least one torsional spring including a coil operatively connected about the shaft and first and second tangs extending away from the shaft;
wherein rotation of the shaft is configured to produce a stress within the at least one torsional spring.

10. An actuator comprising:
a first wire formed from a shape memory alloy;
a second wire formed from a shape memory alloy;
a frame supporting the first and second wires; and
a shaft operatively connected to respective first ends of the first and second wires and configured to rotate in first direction as a function of a dimensional change of the first wire and rotate in a second direction, opposite the first direction, as a function of a dimensional change of the second wire.

11. The actuator of claim 10, wherein:
each of the first and second wires includes a substantially spiral shape; and
the frame includes a plurality of columns supporting the first and second wires.

12. The actuator of claim 10, wherein the first wire includes a first spiral shape and the second wire includes a second spiral shape, the first and second spiral shapes each extend in the same direction.

13. The actuator of claim 10, wherein, the respective dimensional changes of the first and second wires are both a retraction or are both an extension.

14. The actuator of claim 10, wherein the dimensional change in the first and second wires is a function of an electric potential applied to the first and second wires.

15. The actuator of claim 10, further including at least one torsional spring configured to be stressed as a function of the rotation of the shaft in either the first or second direction.

16. The actuator of claim 10, further including a controller configured to receive a signal indicative of an amount of rotation of the shaft and configured to selectively affect the dimensional change of the first or second wires as a function of an amount of energy supplied to the first and second wires.

17. The actuator of claim 16, wherein the signal is indicative of an amount of stress applied to a torsional spring operatively connected between the frame and the shaft.

18. An operator interface device comprising:
a lever movable in at least one axial dimension; and
a first actuator including:
a shaft operatively connected to the lever, and
at least one wire formed from a shape memory alloy operatively connected to the shaft and configured to rotate the shaft in a first direction as a function of energy selectively supplied to the first wire.

19. The operator interface device of claim 18, wherein the actuator further includes:
a second wire formed from a shape memory alloy operatively connected to the shaft and configured to rotate the shaft in a second direction opposite of the first direction as a function of energy selectively supplied to the second wire.

20. The operator interface device of claim 18, wherein the lever is movable in at least two axial dimensions and the shaft of the first actuator is rotated as a function of the displacement of the lever in one of the two axial dimensions, the operator interface device further including:
a second actuator including:
a shaft operatively connected to the lever, and
at least one wire formed from a shape memory alloy operatively connected to the shaft and configured to rotate the shaft in a first direction as a function of energy selectively supplied to the first wire,
wherein the shaft of the second actuator is rotated as a function of the displacement of the lever in the other one of the two axial dimensions.
